(19) United States
(12) Patent Application Publication
(10) Pub. No.: US 2025/0062724 A1
(43) Pub. Date: Feb. 20, 2025

(54) AMPLIFIER CIRCUIT AND COMMUNICATION DEVICE

(71) Applicant: Murata Manufacturing Co., Ltd., Kyoto (JP)

(72) Inventors: Naoki MORIKAWA, Kyoto (JP); Daisuke WATANABE, Kyoto (JP)

(21) Appl. No.: 18/934,518

(22) Filed: Nov. 1, 2024

Related U.S. Application Data
(63) Continuation of application No. PCT/JP2023/017742, filed on May 11, 2023.

(30) Foreign Application Priority Data
May 17, 2022 (JP) 2022-081060

(51) Int. Cl. H03F 1/26; H03F 1/30

(52) U.S. Cl. CPC H03F 1/26; H03F 1/303; H03F 2200/12; H03F 2200/294

(57) ABSTRACT

An amplifier circuit includes a low-noise amplifier configured to amplify a radio-frequency signal, a switching circuit coupled between the low-noise amplifier and an antenna connection terminal, and a bias circuit configured to supply a direct-current bias voltage to the low-noise amplifier 11. The switching circuit includes a terminal coupled to the low-noise amplifier and a terminal coupled to the antenna connection terminal, and a transistor including a gate terminal and a p-type first substrate, configured to alternate the connection and disconnection between the terminals and in response to a voltage applied to the gate terminal. The bias circuit, the terminal, and the first substrate are coupled for direct-current conduction.

### CROSS REFERENCE TO RELATED APPLICATION

This is a continuation of International Application No. PCT/JP2023/017742 filed on May 11, 2023 which claims priority from Japanese Patent Application No. 2022-081060 filed on May 17, 2022. The contents of these applications are incorporated herein by reference in their entireties.

### BACKGROUND ART

### Technical Field

The present disclosure relates to an amplifier circuit and a communication device that amplify radio-frequency signals.

Patent Document 1 discloses a front-end circuit designed to transfer radio-frequency signals while switching among multiple bands. In the front-end circuit, an antenna switch, multiple filters corresponding to multiple bands, a semiconductor switch (LNA switch) that control connection and disconnection between a low-noise amplifier (LNA) and the multiple filters, and the low-noise amplifier are provided in this order. This configuration enables control of transfer or non-transfer of radio-frequency signals in designated bands.
Patent Document 1: U.S. Patent Application Publication No. 2020/0343933

### BRIEF SUMMARY

In the front-end circuit (amplifier circuit) disclosed in Patent Document 1, transfer loss may increase due to the on-resistance of the semiconductor switch during the transfer of radio-frequency signals, or off-leak current may flow through the semiconductor switch when radio-frequency signals are not being transferred. One possible solution to address these problems is to include additional circuits designed to reduce the on-resistance and off-leak current of the semiconductor switch. However, incorporating these additional circuits increases the size of the amplifier circuit.

The present disclosure provides a miniaturized amplifier circuit and a miniaturized communication device that are capable of transferring radio-frequency signals with low loss.

An amplifier circuit according to an embodiment of the present disclosure includes a first input terminal configured to receive a radio-frequency signal, an amplifier configured to amplify the radio-frequency signal, a switching circuit coupled between the amplifier and the first input terminal, and a bias circuit configured to supply a direct-current bias voltage to the amplifier. The switching circuit includes a first terminal coupled to the amplifier, and a second terminal coupled to the first input terminal, and a first switch including a transistor that has a first control terminal and a first substrate of a first conductivity type, the first switch being configured to alternate connection and disconnection between the first terminal and the second terminal in response to a voltage applied to the first control terminal. The bias circuit, the first terminal, and the first substrate are coupled for direct-current conduction.

The present disclosure provides a miniaturized amplifier circuit and a miniaturized communication device that are capable of transferring radio-frequency signals with low loss.

### BRIEF DESCRIPTION OF THE DRAWINGS

FIG. 1 is a circuit configuration diagram of an amplifier circuit and a communication device according to an embodiment.

FIG. 2A illustrates a partial circuit configuration of a switching circuit and adjacent circuits according to the embodiment.

FIG. 2B provides schematic sectional diagrams of transistors that constitute the switching circuit according to the embodiment.

FIG. 3 illustrates a partial circuit configuration of a switching circuit and adjacent circuits according to a comparative example.

FIG. 4 illustrates a partial circuit configuration of a switching circuit and adjacent circuits according to a modification.

FIG. 5 illustrates a circuit state of the switching circuit and adjacent circuits according to the modification during signal transfer.

### DETAILED DESCRIPTION

Hereinafter, embodiments of the present disclosure will be described in detail. It should be noted that the embodiments described below provide comprehensive or specific examples. Specifics including numerical values, shapes, materials, constituent elements, arrangements of the constituent elements, and modes of connection given in the following embodiments are mere instances and are not intended to limit the present disclosure. Among the constituent elements in the following embodiments and modifications, constituent elements not recited in any of the independent claims are described as arbitrary constituent elements. The size or size ratio of the constituent elements illustrated in the drawings is not necessarily presented in an exact manner. Like reference symbols denote substantially like configuration elements in the drawings, and redundant descriptions thereof can be omitted or simplified.

In the following description, words used to express relationships between elements, such as parallel and vertical, words used to express the shape of an element, such as rectangular, and numerical ranges do not necessarily denote the exact meanings but denote substantially the same meanings involving, for example, several percent differences.

In the following embodiments, the expression “A and B are coupled” includes the case where A and B are in contact with each other and also includes the case where A and B are electrically connected to each other via, for example, a conductive electrode, a conductive terminal, an interconnection, or another circuit component. The expression “coupled between A and B” means that a circuit element is coupled to both A and B while the circuit element is positioned between A and B.

In the present disclosure, the expression “a component A is provided in series in a path B” means that both of the signal input end and the signal output end of the component A are coupled to a wire line, an electrode, or a terminal that constitute the path B.

In the present disclosure, the term “path” refers to a transmission line formed by, for example, a wire line for transferring radio-frequency signals, an electrode directly coupled to the wire line, and a terminal directly coupled to the wire line or electrode.

### Embodiment

### 1. Configuration of Amplifier Circuit 1 and Communication Device 4

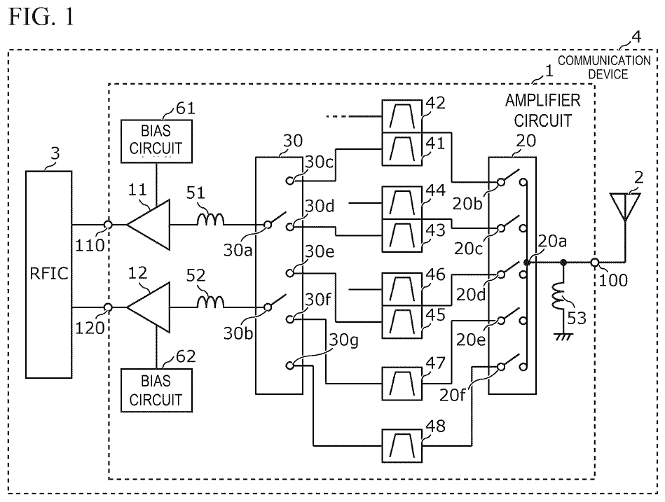

A circuit configuration of an amplifier circuit 1 and a communication device 4 according to the present embodiment will be described with reference to FIG. 1. FIG. 1 is a circuit configuration diagram of the amplifier circuit 1 and the communication device 4 according to the embodiment.

### [1.1 Circuit Configuration of Communication Device 4]

First, a circuit configuration of the communication device 4 will be described. As illustrated in FIG. 1, the communication device 4 includes the amplifier circuit 1, an antenna 2, and a radio-frequency signal processing circuit (RFIC) 3.

The amplifier circuit 1 is operable to transfer radio-frequency signals between the antenna 2 and the RFIC 3. A detailed circuit configuration of the amplifier circuit 1 will be described later.

The antenna 2 is coupled to an antenna connection terminal 100 of the amplifier circuit 1. The antenna 2 is operable to transmit radio-frequency signals outputted from the amplifier circuit 1 and to receive radio-frequency signals from outside and output the radio-frequency signals to the amplifier circuit 1.

The RFIC 3 is an example of a signal processing circuit for processing radio-frequency signals. Specifically, the RFIC 3 is operable to process, for example by down-conversion, receive signals inputted through receive paths of the amplifier circuit 1 and output the receive signals generated through the signal processing to a baseband signal processing circuit (BBIC, not illustrated). The RFIC 3 is also operable to process, for example by up-conversion, transmit signals inputted from the BBIC and output the transmit signals generated by the signal processing to transmit paths of the amplifier circuit 1. The RFIC 3 includes a control unit for controlling elements included in the amplifier circuit 1, such as switches, amplifiers, and bias circuits. The control unit of the RFIC3 is operable to control, for example, the supply voltage and bias voltage supplied to the amplifiers included in the amplifier circuit 1. Specifically, the RFIC 3 outputs digital control signals to bias circuits 61 and 62. The bias voltages set by the digital control signals can be supplied to the amplifiers included in the amplifier circuit 1 to the bias circuits 61 and 62.

The function of the control unit of the RFIC 3 may be partially or entirely implemented outside the RFIC 3; for example, the function of the control unit of the RFIC 3 may be partially or entirely implemented in the BBIC or the amplifier circuit 1.

### [1.2 Circuit Configuration of Amplifier Circuit 1]

Next, a circuit configuration of the amplifier circuit 1 will be described. As illustrated in FIG. 1, the amplifier circuit 1 includes low-noise amplifiers 11 and 12, switching circuits 20 and 30, bias circuits 61 and 62, filters 41, 42, 43, 44, 45, 46, 47, and 48, inductors 51, 52, and 53, the antenna connection terminal 100, and radio-frequency output terminals 110 and 120.

The antenna connection terminal 100 is an example of a first input terminal configured to receive a radio-frequency signal. The antenna connection terminal 100 is coupled to the antenna 2. The radio-frequency output terminals 110 and 120 are coupled to the RFIC3.

The low-noise amplifier 11 is an example of an amplifier that amplifies radio-frequency signals. The input end of the low-noise amplifier 11 is coupled to a terminal 30a of the switching circuit 30 via the inductor 51, and the output end of the low-noise amplifier 11 is coupled to the radio-frequency output terminal 110. The low-noise amplifier 12 is an example of an amplifier that amplifies radio-frequency signals. The input end of the low-noise amplifier 12 is coupled to a terminal 30b of the switching circuit 30 via the inductor 52, and the output end of the low-noise amplifier 12 is coupled to the radio-frequency output terminal 120.

The switching circuit 30 is coupled between the low-noise amplifiers 11 and 12 and the antenna connection terminal 100. The switching circuit 30 has the terminal 30a (a first terminal), the terminal 30b (a first terminal), a terminal 30c (a second terminal), and terminals 30d, 30e, 30f, and 30g. The switching circuit 30 is operable to alternate the connection and disconnection of the terminal 30a with each of the terminals 30c, 30d, 30e, 30f, and 30g, and to alternate the connection and disconnection of the terminal 30b with the each of the terminals 30c, 30d, 30e, 30f, and 30g. The switching circuit 30 includes transistors coupled to the respective terminals 30a to 30g.

The bias circuit 61 is operable to supply a direct-current (DC) bias voltage to the low-noise amplifier 11. The bias circuit 62 is operable to supply a DC bias voltage to the low-noise amplifier 12. The bias circuit 61 supplies a DC bias voltage to the transistor coupled to the terminal 30a via the low-noise amplifier 11, the inductor 51, and the terminal 30a. The bias circuit 62 supplies a DC bias voltage to the transistor coupled to the terminal 30b via the low-noise amplifier 12, the inductor 52, and the terminal 30b.

The switching circuit 20 is coupled between the antenna connection terminal 100 and the filters 41 to 48. The switching circuit 20 has terminals 20a, 20b, 20c, 20d, 20e, and 20f. The switching circuit 20 is operable to alternate the connection and disconnection of the terminal 20a with each of the terminals 20b, 20c, 20d, 20e, and 20f.

The filter 41 is a receive filter having a pass band that includes the downlink operating band of a band A for frequency division duplex (FDD). The filter 42 is a transmit filter having a pass band that includes the uplink operating band of the band A. The output end of the filter 42 and the input end of the filter 41 are coupled to the antenna connection terminal 100 via the terminal 20b. The output end of the filter 41 is coupled to the terminal 30c.

The filter 43 is a receive filter having a pass band that includes the downlink operating band of a band B for FDD. The filter 44 is a transmit filter having a pass band that includes the uplink operating band of the band B. The output end of the filter 44 and the input end of the filter 43 are coupled to the antenna connection terminal 100 via the terminal 20c. The output end of the filter 43 is coupled to the terminal 30d.

The filter 45 is a receive filter having a pass band that includes the downlink operating band of a band C for FDD. The filter 46 is a transmit filter having a pass band that includes the uplink operating band of the band C. The output end of the filter 46 and the input end of the filter 45 are coupled to the antenna connection terminal 100 via the terminal 20d. The output end of the filter 45 is coupled to the terminal 30e.

The filter 47 is a transmit/receive filter having a pass band that includes a band D for time division duplex (TDD). One end of the filter 47 is coupled to the antenna connection terminal 100 via the terminal 20e, and the other end of the filter 47 is coupled to the terminal 30f.

The filter 48 is a transmit/receive filter having a pass band that includes a band E for TDD. One end of the filter 48 is coupled to the antenna connection terminal 100 via the terminal 20f, and the other end of the filter 48 is coupled to the terminal 30g.

Each of the filters 44 to 48 may be coupled to an antenna connection terminal (a second input terminal) different from the antenna connection terminal 100 via the switching circuit 20.

It is desirable that at least one of the filters 41, 43, 45, 47, and 48 is an acoustic wave filter.

Because acoustic wave filters exhibit capacitive characteristics, the acoustic wave filter does not pass the DC bias voltages supplied from the bias circuits 61 and 62, thereby preventing the DC bias voltages from leaking from the switching circuit 30 to the antenna connection terminal 100 side.

The FDD and TDD bands represent frequency bands determined by, for example, standards organizations such as the 3rd Generation Partnership Project (3GPP) (registered trademark) and the Institute of Electrical and Electronics Engineers (IEEE)) for communication systems built using a radio access technology (RAT). As the communication system in the present embodiment, for example, a 4th Generation Long Term Evolution (4G LTE) system, 5th Generation New Radio (5G NR) system, and Wireless Local Area Network (WLAN) system may be used, but these are not to be interpreted as limiting.

One end of the inductor 51 is coupled to the terminal 30a, and the other end of the inductor 51 is coupled to the low-noise amplifier 11. The inductor 51 is operable to provide impedance matching between the low-noise amplifier 11, and the switching circuit 30 and the filters 41 to 48. One end of the inductor 52 is coupled to the terminal 30b, and the other end of the inductor 52 is coupled to the low-noise amplifier 12. The inductor 52 is operable to provide impedance matching between the low-noise amplifier 12, and the switching circuit 30 and the filters 41 to 48. The inductor 53 is coupled between ground and the path connecting the antenna connection terminal 100 and the terminal 20a. The inductor 53 is operable to provide impedance matching between the antenna 2, and the switching circuit 20 and the filters 41 to 48.

In the amplifier circuit 1 according to the present embodiment, no inductor is coupled between ground and the path connecting the terminal 30a and low-noise amplifier 11. No inductor is coupled between ground and the path connecting the terminal 30b and the low-noise amplifier 12. For example, a connecting member such as an electrode or via-conductor connects ground to the path connecting the terminal 30b and the low-noise amplifier 12. With this configuration, the bias circuit 61 can supply a DC bias voltage through the low-noise amplifier 11 and the terminal 30a to the transistor coupled to the terminal 30a, and the bias circuit 62 can supply a DC bias voltage through the low-noise amplifier 12 and the terminal 30b to the transistor coupled to the terminal 30b.

It is sufficient for the amplifier circuit 1 to include at least the low-noise amplifier 11, the switching circuit 30, the bias circuit 61, and the antenna connection terminal 100. It is sufficient for the switching circuit 30 to have at least the terminals 30a and 30c. Instead of the low-noise amplifier 11 that amplifies receive signals, a power amplifier that amplifies transmit signals may be provided. When such a power amplifier is provided, the switching circuit 30 is coupled between the RFIC3 and the power amplifier.

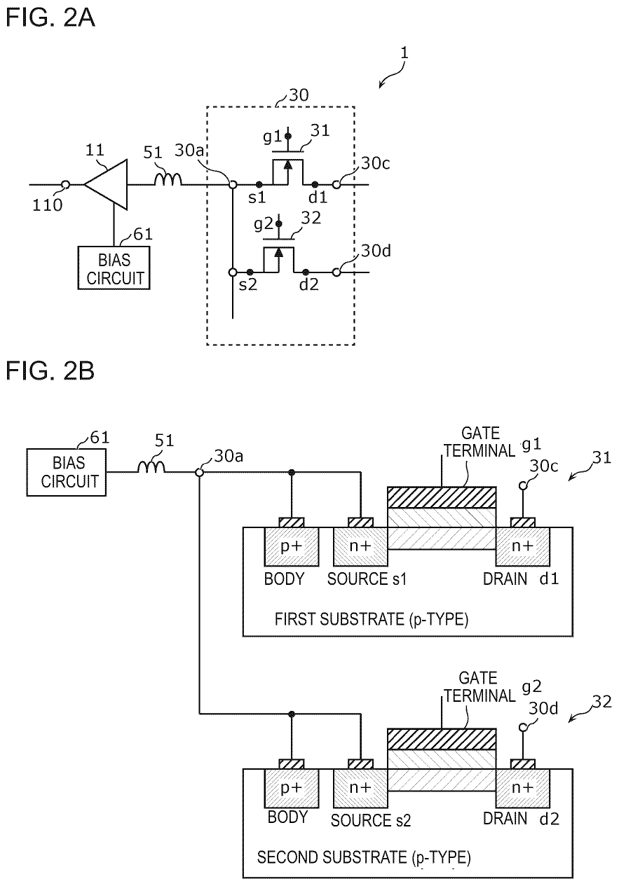

FIG. 2A illustrates a partial circuit configuration of the switching circuit 30 and adjacent circuits included in the amplifier circuit 1 according to the embodiment. Specifically, FIG. 2A illustrates a detailed circuit configuration of the switching circuit 30.

As illustrated in FIG. 2A, the switching circuit 30 has the terminals 30a, 30c, and 30d and transistors 31 and 32. The terminals 30b, 30e, 30f, and 30g are not illustrated in the drawing.

FIG. 2B provides schematic sectional diagrams of the transistors 31 and 32 that constitute the switching circuit 30 according to the embodiment.

The transistor 31 is an example of a first switch. The transistor 31 is a field effect transistor (FET) that includes a first substrate, a gate terminal g1, a source s1, and a drain d1. In the present embodiment, the first substrate is of p-type (a first conductivity type). The gate terminal g1 corresponds to a first control terminal. The source s1 corresponds to a first region of n-type (a second conductivity type) provided within the first substrate. The drain d1 corresponds to a second region of n-type (a second conductivity type) provided within the first substrate. The transistor 31 is an n-type FET.

The transistor 32 is an example of a first switch. The transistor 32 is a FET that includes a second substrate, a gate terminal g2, a source s2, and a drain d2. In the present embodiment, the second substrate is of p-type (a first conductivity type). The gate terminal g2 is a second control terminal. The source s2 is a third region of n-type (a second conductivity type) provided within the second substrate. The drain d2 is a fourth region of n-type (a second conductivity type) provided within the second substrate. The transistor 32 is an n-type FET.

In the transistor 31, the first substrate may be of n-type, the source s1 may correspond to a p-type first region provided within the first substrate, and the drain d1 may correspond to a p-type second region provided within the first substrate, and the transistor 31 may correspond to a p-type FET. In the transistor 32, the second substrate may be of n-type, the source s2 may be a p-type third region provided within the second substrate, and the drain d2 may be a p-type fourth region provided within the second substrate, and the transistor 32 may be a p-type FET.

As illustrated in FIGS. 2A and 2B, the source s1 is coupled to the terminal 30a, and the drain d1 is coupled to the terminal 30c. The source s2 is coupled to the terminal 30a, and the drain d2 is coupled to the terminal 30d.

The transistor 31 is operable to alternate the connection and disconnection between the terminals 30a and 30c in response to the voltage applied to the gate terminal g1. The transistor 32 is operable to alternate the connection and disconnection between the terminals 30a and 30d in response to the voltage applied to the gate terminal g2.

Here, as illustrated in FIGS. 2A and 2B, the first substrate and the source s1 of the transistor 31 are coupled to the terminal 30a. The bias circuit 61, the terminal 30a, and the first substrate of the transistor 31 are coupled for direct-current conduction. Specifically, a DC bias voltage can be applied as a substrate bias voltage for the transistor 31 from the bias circuit 61 through the terminal 30a and the source s1. The state in which the bias circuit 61 and the first substrate of the transistor 31 are coupled for direct-current conduction refers to a circuit state in which no DC-blocking element (for example, a capacitor) is placed between the bias circuit 61 and the first substrate.

As illustrated in FIGS. 2A and 2B, the second substrate and the source s2 of the transistor 32 are coupled to the terminal 30a. The bias circuit 61, the terminal 30a, and the second substrate of the transistor 32 are coupled for direct-current conduction. Specifically, a DC bias voltage can be applied as a substrate bias voltage for the transistor 32 from the bias circuit 61 through the terminal 30a and the source s2.

The bias voltage supplied from the bias circuit 61 to the first substrate of the transistor 31 and the second substrate of the transistor 32 is referred to as a substrate bias voltage.

In general, when a transistor is used as a switch, the transfer loss (Ron) in the conducting state (active state) is expressed by the following expression 1. In Expression 1, p represents the mobility, Cox represents the gate capacitance per unit area, W represents the gate width, L represents the gate length, Vgs represents the gate-source voltage, and Vt represents the threshold voltage.

$$[ Math . 1 ]$$

$$Ron = \frac{1}{μ Cox \frac{W}{L} ( V gs - Vt )} \qquad ( Expression 1 )$$

According to Expression 1, when the threshold voltage Vt of the transistor is low, the transfer loss Ron in the conducting state (active state) can be reduced. The threshold voltage Vt can be controlled by applying a substrate bias voltage to the transistor. For example, the threshold voltage Vt can be reduced by applying a positive substrate bias voltage to the n-type FET to reduce, and as a result, the transfer loss Ron can be reduced. However, when the threshold voltage Vt is constantly low, the off-leak current generated when the transistor is in the non-conducting state (inactive state) can become large.

In the amplifier circuit 1 according to the present embodiment, the substrate bias voltage supplied to the transistor 31 can be supplied, without necessarily requiring a dedicated path, from the bias circuit 61, which also supplies the bias voltage supplied to the low-noise amplifier 11, through the low-noise amplifier 11 and the terminal 30a. This configuration reduces the number of bias circuits, thereby miniaturizing the amplifier circuit 1. Furthermore, the threshold voltage Vt of the transistor 31 can be lowered by applying a substrate bias voltage, thereby reducing the transfer loss Ron of the transistor 31. As a result, the amplifier circuit 1 can transfer radio-frequency signals with low loss. Because receive signals can be supplied to the low-noise amplifier 11 with low loss, degradation of receive sensitivity can be suppressed. When the low-noise amplifier 11 is in the off-state, the substrate bias voltage can be reduced, and the threshold voltage Vt can be increased, thereby reducing the off-leak current when radio-frequency signals are not amplified.

In the amplifier circuit 1 according to the present embodiment, the substrate bias voltage supplied to the transistor 32 can be supplied, without necessarily requiring a dedicated path, from the bias circuit 62, which also supplies the bias voltage supplied to the low-noise amplifier 12, through the low-noise amplifier 12 and the terminal 30a. This configuration reduces the number of bias circuits, thereby miniaturizing the amplifier circuit 1. Furthermore, the threshold voltage Vt of the transistor 32 can be lowered by applying a substrate bias voltage, thereby reducing the transfer loss Ron of the transistor 32. When the low-noise amplifier 12 is in the off-state, the substrate bias voltage can be reduced, and the threshold voltage Vt can be increased, thereby reducing the off-leak current when radio-frequency signals are not amplified.

The transistors 31 and 32 may be FETs as described above, or may be bipolar transistors. When the transistors 31 and 32 are bipolar transistors, for example, the source corresponds to the emitter, the drain corresponds to the collector, and the gate terminal corresponds to the base terminal.

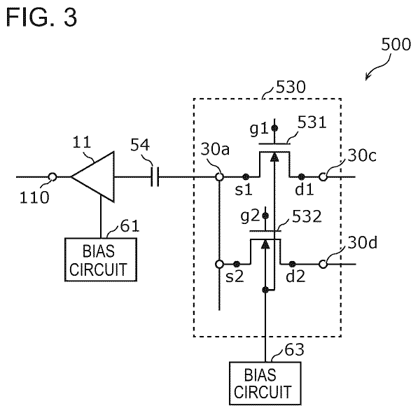

FIG. 3 is a circuit configuration diagram of a switching circuit 530 and adjacent circuits included in an amplifier circuit 500 according to a comparative example. The amplifier circuit 500 according to the comparative example is an example of a known amplifier circuit. The amplifier circuit 500 according to the comparative example includes at least a low-noise amplifier 11, the switching circuit 530, bias circuits 61 and 63, and a capacitor 54. The amplifier circuit 500 according to the comparative example differs from the amplifier circuit 1 according to the embodiment by additionally including the bias circuit 63 and the capacitor 54, as well as in the connection configuration of the switching circuit 530. The following describes the amplifier circuit 500 according to the comparative example with a main focus on configurational features different from the amplifier circuit 1 according to the embodiment, and descriptions of the same configurational features as the amplifier circuit 1 according to the embodiment will not be repeated.

The capacitor 54 is coupled between the low-noise amplifier 11 and a terminal 30a. The capacitor 54 is operable to block the flow of DC components such as DC bias voltages.

The bias circuit 61 is operable to supply a DC bias voltage to the low-noise amplifier 11. The DC bias voltage supplied from the bias circuit 61 is blocked by the capacitor 54 and not supplied to the switching circuit 530.

The bias circuit 63 is operable to supply a DC bias voltage to transistors 531 and 532. The DC bias voltage supplied from the bias circuit 63 is blocked by the capacitor 54 and not supplied to the low-noise amplifier 11.

The switching circuit 530 has terminals 30a, 30c, and 30d and the transistors 531 and 532.

The transistor 531 is a FET that includes a first substrate, a gate terminal g1, a source s1, and a drain d1. In the comparative example, the first substrate is of p-type (a first conductivity type). The source s1 corresponds to a first region of n-type (a second conductivity type) provided within the first substrate. The drain d1 corresponds to a second region of n-type (a second conductivity type) provided within the first substrate. The transistor 531 corresponds to an n-type FET.

The transistor 532 is a FET that includes a second substrate, a gate terminal g2, a source s2, and a drain d2. In the comparative example, the second substrate is of p-type (a first conductivity type). The source s2 is a third region of n-type (a second conductivity type) provided within the second substrate. The drain d2 is a fourth region of n-type (a second conductivity type) provided within the second substrate. The transistor 532 is an n-type FET.

As illustrated in FIG. 3, the source s1 is coupled to the terminal 30a, and the drain d1 is coupled to the terminal 30c. The source s2 is coupled to the terminal 30a, and the drain d2 is coupled to the terminal 30d.

The transistor 531 is operable to alternate the connection and disconnection between the terminals 30a and 30c in response to the voltage applied to the gate terminal g1. The transistor 532 is operable to alternate the connection and disconnection between the terminals 30a and 30d in response to the voltage applied to the gate terminal g2.

Here, as illustrated in FIG. 3, the first substrate of the transistor 531 is not coupled to the terminal 30a. The bias circuit 61 and the first substrate of the transistor 531 are not coupled for direct-current conduction. A DC bias voltage can be applied as a substrate bias voltage for the transistor 531 from the bias circuit 63. The second substrate of the transistor 532 is not coupled to the terminal 30a. The bias circuit 61 and the second substrate of the transistor 532 are not coupled for direct-current conduction. A DC bias voltage can be applied as a substrate bias voltage for the transistor 532 from the bias circuit 63.

In the amplifier circuit 500 according to the comparative example, the threshold voltage Vt of the transistors 531 and 532 can be lowered by applying a substrate bias voltage to the transistors 531 and 532, thereby reducing the transfer loss Ron of the transistors 531 and 532. However, the substrate bias voltage supplied to the transistors 531 and 532 are not supplied from the bias circuit 61, which supplies the bias voltage to the low-noise amplifier 11, but rather from the bias circuit 63, which is provided for supplying the substrate bias voltage. Because the bias circuit 61, which supplies the bias voltage to the low-noise amplifier 11, and the bias circuit 63, which supplies the substrate bias voltage, are provided, the amplifier circuit 500 increases in size. When the low-noise amplifier 11 is in the off-state, it is desirable to reduce the substrate bias voltage to minimize the off-leak current. To achieve this, the bias voltage needs to be controlled by coordinating the operation of the bias circuits 61 and 63. As a result, the bias circuit control becomes complex.

By contrast, in the amplifier circuit 1 according to the present embodiment, the substrate bias voltage supplied to the transistor 31 is supplied from the bias circuit 61 that supplies the bias voltage to the low-noise amplifier 11, thereby reducing the number of bias circuits and miniaturizing the amplifier circuit 1. Furthermore, the threshold voltage Vt of the transistor 31 can be lowered by applying a substrate bias voltage, thereby reducing the transfer loss Ron of the transistor 31. The substrate bias voltage supplied to the transistor 32 is supplied from the bias circuit 61 that supplies the bias voltage to the low-noise amplifier 11, thereby reducing the number of bias circuits and miniaturizing the amplifier circuit 1. Furthermore, the threshold voltage Vt of the transistor 32 can be lowered by applying a substrate bias voltage, thereby reducing the transfer loss Ron of the transistor 32. As a result, the amplifier circuit 1 can transfer radio-frequency signals with low loss. When the low-noise amplifier 11 is in the off-state, the substrate bias voltage can be reduced, and the threshold voltage Vt can be increased, thereby reducing the off-leak current by controlling only the bias circuit 61.

### [1.3 Circuit Configuration of Amplifier Circuit 1A According to Modification]

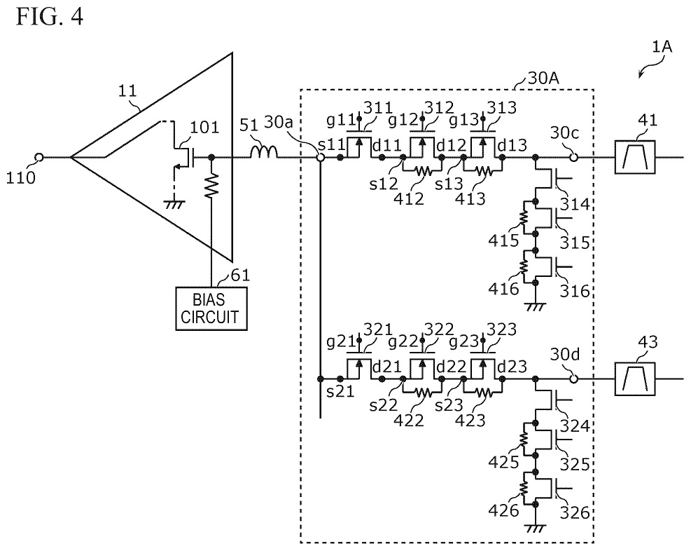

Next, a circuit configuration of an amplifier circuit 1A according to a modification will be described. As illustrated in FIG. 4, the amplifier circuit 1A includes a low-noise amplifier 11, a switching circuit 30A, a bias circuit 61, filters 41 and 43, an inductor 51, and a radio-frequency output terminal 110.

The amplifier circuit 1A according to the present modification include a low-noise amplifier 12, a bias circuit 62, filters 42 and 44 to 48, inductors 52 and 53, a radio-frequency output terminal 120, and an antenna connection terminal 100 illustrated in FIG. 1.

The amplifier circuit 1A according to the present modification differs from the amplifier circuit 1 according to the embodiment in the configuration of the switching circuit 30A. The following describes the amplifier circuit 1A according to the present modification with a main focus on configurational features different from the amplifier circuit 1 according to the embodiment, and descriptions of the same configurational features as the amplifier circuit 1 according to the embodiment will not be repeated.

The low-noise amplifier 11 includes an amplifier transistor 101. The amplifier transistor 101 is, for example, an n-type FET and has a gate terminal, a drain terminal, and a source terminal. Radio-frequency signals can be input from the gate, amplified, and output from the drain terminal. Circuit elements such as transistors, inductors, or capacitors may be coupled to the gate terminal, the drain terminal, and the source terminal of the amplifier transistor 101. The amplifier transistor 101 may be a p-type FET or, for example, a bipolar transistor. When the amplifier transistor 101 is a bipolar transistor, for example, the source terminal corresponds to the emitter terminal, the drain terminal corresponds to the collector terminal, and the gate terminal corresponds to the base terminal.

The bias circuit 61 supplies a DC bias voltage to the gate terminal of the amplifier transistor 101. The bias circuit 61 supplies a DC bias voltage to transistors 311, 312, 313, 321, 322, and 323 coupled to the terminal 30a via the low-noise amplifier 11, the inductor 51, and a terminal 30a.

The switching circuit 30A is coupled between the low-noise amplifier 11 and the antenna connection terminal 100. The switching circuit 30A has the terminal 30a (a first terminal), a terminal 30c (a second terminal), and a terminal 30d, and transistors 311, 312, 313, 314, 315, 316, 321, 322, 323, 324, 325, and 326. The switching circuit 30A alternates the connection and disconnection between the terminal 30a and each of the terminals 30c and 30d by alternating the conducting state and the non-conducting state of the transistors 311 to 316 and 321 to 326.

The terminal 30a is coupled to the low-noise amplifier 11 via the inductor 51. The terminal 30c is coupled to the antenna connection terminal 100 via the filter 41 and the switching circuit 20. The terminal 30d is coupled to the antenna connection terminal 100 via the filter 43 and the switching circuit 20. The terminal 30d may be coupled to a different antenna connection terminal (a second input terminal) from the antenna connection terminal 100 (a first input terminal).

The transistors 311 to 313 are an example of one or more first switches. The transistors 311 to 313 are series switches coupled in series between the terminal 30a (a first terminal) and the terminal 30c (a second terminal). The transistor 311 is a FET that includes a third substrate, a gate terminal g11, a source s11, and a drain d11. The transistor 312 is a FET that includes a fourth substrate, a gate terminal g12, a source s12, and a drain d12. The Transistor 313 is a FET that includes a fifth substrate, a gate terminal g13, a source s13, and a drain d13. In the present modification, the third substrate to the fifth substrate are of p-type (a first conductivity type). The gate terminals g11 to g13 correspond to a first control terminal. The sources s11 to s13 correspond to a first region of n-type (a second conductivity type) provided within the third substrate to the fifth substrate. The drains d11 to d13 correspond to a second region of n-type (a second conductivity type) provided within the third substrate to the fifth substrate. The transistors 311 to 313 are n-type FETs. The source s11 is coupled to the terminal 30a and the third substrate. The drain d11 is coupled to the source s12 and the fourth substrate. The drain d12 is coupled to the source s13 and the fifth substrate. The drain d13 is coupled to the terminal 30c.

With the connection configuration described above, the bias voltage output by the bias circuit 61 can be applied to the third substrate through the low-noise amplifier 11, the terminal 30a, and the source s1l. When the transistors 311, 312 and 313 are in the on-state, the bias voltage output by the bias circuit 61 can be applied to the fourth substrate through the source s12 and to the fifth substrate via through the source s13. Because the substrate bias voltage can be applied to each of the transistors 311 to 313 when the transistors 311 to 313 are in the on-state, this configuration reduces the on-resistance of the transistors 311 to 313. Because the substrate bias voltage cannot be applied to each of the transistors 311 to 313 when the transistors 311 to 313 are in the off-state, this configuration reduces the off-leak current of the transistors 311 to 313.

The transistors 314 to 316 are an example of one or more second switches. The transistors 314 to 316 are shunt switches coupled in series with each other between ground and the path connecting the terminals 30a and 30c. The transistor 314 is a FET that includes a sixth substrate, a gate terminal, a source, and a drain. The transistor 315 is a FET that includes a seventh substrate, a gate terminal, a source, and a drain. The transistor 316 is a FET that includes an eighth substrate, a gate terminal, a source, and a drain. In the present modification, the sixth substrate to the eighth substrate are of p-type (a first conductivity type). The sources of the transistors 314 to 316 correspond to a region of n-type (a second conductivity type) provided within the sixth substrate to the eighth substrate. The drains of the transistors 314 to 316 correspond to a region of n-type (a second conductivity type) provided within the sixth substrate to the eighth substrate. The transistors 314 to 316 are n-type FETs.

The transistors (first switches) coupled in series with each other between the terminals 30a and 30c may be a single transistor, and it may be possible that the transistors 312 and 313 are not provided. The transistors coupled in series with each other between the terminals 30a and 30c may be four or more.

Among the transistors 311 to 316, the transistor 311 is coupled closest to the low-noise amplifier 11.

In this configuration, the transistor 311 coupled closest to the low-noise amplifier 11 corresponds not to the second switch coupled between ground and the path connecting the terminals 30a and 30c, but rather to the first switch provided in series in the path connecting the terminals 30a and 30c. As a result, the bias voltage supplied by the bias circuit 61 can be supplied to at least the third substrate of the transistor 311 nearest to the low-noise amplifier 11.

The transistors (second switches) coupled in series with each other between ground and the path connecting the terminals 30a and 30c may be a single transistor, and it may be possible that the transistors 315 and 316 are not provided. The transistors coupled in series with each other between ground and the path connecting the terminals 30a and 30c may be four or more.

With this configuration, radio-frequency signals can be transferred with low loss by turning the first switch and the second switch on or off in an exclusive manner. The switch coupled closest to the amplifier is not the second switch but rather the first switch. As a result, the bias voltage can be supplied to the substrate of the first switch.

The third substrate to the fifth substrate may be a single substrate. The sixth substrate to the eighth substrate may be a single substrate. The third substrate to the eighth substrate may be a single substrate.

The transistors 321 to 323 are an example of one or more third switches. The transistors 321 to 323 are series switches coupled in series between the terminal 30a (a first terminal) and the terminal 30d (a third terminal). The transistor 321 is a FET that includes a ninth substrate, a gate terminal g21, a source s21, and a drain d21. The transistor 322 is a FET that includes a tenth substrate, a gate terminal g22, a source s22, and a drain d22. The transistor 323 is a FET that includes an eleventh substrate, a gate terminal g23, a source s23, and a drain d23. In the present modification, the ninth substrate to the eleventh substrate are of p-type (a first conductivity type). The gate terminals g21 to g23 correspond to a first control terminal. The sources s21 to s23 correspond to a third region of n-type (a second conductivity type) provided within the ninth substrate to the eleventh substrate. The drains d21 to d23 correspond to a fourth region of n-type (a second conductivity type) provided within the ninth substrate to the eleventh substrate. The transistors 321 to 323 are n-type FETs. The source s21 is coupled to the terminal 30a and the ninth substrate. The drain d21 is coupled to the source s22 and the tenth substrate. The drain d22 is coupled to the source s23 and the eleventh substrate. The drain d23 is coupled to the terminal 30c.

With the connection configuration described above, the bias voltage output by the bias circuit 61 can be applied to the ninth substrate through the low-noise amplifier 11, the terminal 30a, and the source s21. When the transistors 321, 322 and 323 are in the on-state, the bias voltage output by the bias circuit 61 can be applied to the tenth substrate through the source s22 and to the eleventh substrate via through the source s23. Because the substrate bias voltage can be applied to each of the transistors 321 to 323 when the transistors 321 to 323 are in the on-state, this configuration reduces the on-resistance of the transistors 321 to 323. Because the substrate bias voltage cannot be applied to each of the transistors 321 to 323 when the transistors 321 to 323 are in the off-state, this configuration reduces the off-leak current of the transistors 321 to 323.

The transistors 324 to 326 are an example of one or more fourth switches. The transistors 324 to 326 are shunt switches coupled in series with each other between ground and the path connecting the terminals 30a and 30d. The transistor 324 is a FET that includes a twelfth substrate, a gate terminal, a source, and a drain. The transistor 325 is a FET that includes a thirteenth substrate, a gate terminal, a source, and a drain. The transistor 326 is a FET that includes a fourteenth substrate, a gate terminal, a source, and a drain. In the present modification, the twelfth substrate to the fourteenth substrate are of p-type (a first conductivity type). The sources of the transistors 324 to 326 correspond to a region of n-type (a second conductivity type) provided within the twelfth substrate to the fourteenth substrate. The drains of the transistors 324 to 326 correspond to a region of n-type (a second conductivity type) provided within the twelfth substrate to the fourteenth substrate. The transistors 324 to 326 are n-type FETs.

The transistors (third switches) coupled in series with each other between the terminals 30a and 30d may be a single transistor, and it may be possible that the transistors 322 and 323 are not provided. The transistors coupled in series with each other between the terminals 30a and 30d may be four or more.

Among the transistors 321 to 326, the transistor 321 is coupled closest to the low-noise amplifier 11.

In this configuration, the transistor 321 coupled closest to the low-noise amplifier 11 corresponds not to the fourth switch coupled between ground and the path connecting the terminals 30a and 30d, but rather to the third switch provided in series in the path connecting the terminals 30a and 30d. As a result, the bias voltage supplied by the bias circuit 61 can be supplied to at least the ninth substrate of the transistor 321 nearest to the low-noise amplifier 11.

The transistors (fourth switches) coupled in series with each other between ground and the path connecting the terminals 30a and 30d may be a single transistor, and it may be possible that the transistors 325 and 326 are not provided. The transistors coupled in series with each other between ground and the path connecting the terminals 30a and 30d may be four or more.

With this configuration, radio-frequency signals can be transferred with low loss by turning the third switch and the fourth switch on or off in an exclusive manner. The switch coupled closest to the low-noise amplifier 11 is not the fourth switch but rather the third switch. As a result, the bias voltage can be supplied to the ninth substrate of the third switch.

The ninth substrate to the eleventh substrate may be a single substrate. The twelfth substrate to the fourteenth substrate may be a single substrate. The ninth substrate to the fourteenth substrate may be a single substrate. The third substrate to the fourteenth substrate may be a single substrate.

The transistor 312 includes a resistive element 412 coupling the source s12 and the drain d12. The transistor 313 includes a resistive element 413 coupling the source s13 and the drain d13. The transistor 311 does not include a resistive element coupling the source s11 and the drain d11.

The transistor 322 includes a resistive element 422 coupling the source s22 and the drain d22. The transistor 323 includes a resistive element 423 coupling the source s23 and the drain d23. The transistor 321 does not include a resistive element coupling the source s21 and the drain d21.

The resistive elements 412 and 413 prevent the transistors 312 and 313 from being damaged by external surge voltages. However, in the signal path (off signal path in which the low-noise amplifier 11 is in the off-state, the bias voltage from other signal paths can be supplied through the resistive elements. In this case, the threshold voltages of the transistors 312 and 313 can decrease to the on-state, and radio-frequency signals can leak into the off signal path, thereby degrading isolation characteristics. In contrast, because the transistor 311 does not include a resistive element, the supply of the bias voltage output from the bias circuit 61 to the transistors 312 and 313 through the resistive elements 412 and 413 can be hindered. As a result, the degradation of isolation characteristics can be suppressed.

The transistor not including a resistive element coupling the drain and the source is not necessarily the transistor 311. It is sufficient that at least one of the transistors 311 to 313 does not include a resistive element coupling the drain and the source.

The resistive elements 422 and 423 prevent the transistors 322 and 323 from being damaged by external surge voltages. However, in the signal path (off signal path in which the low-noise amplifier 11 is in the off-state, the bias voltage from other signal paths can be supplied through the resistive elements. In this case, the threshold voltages of the transistors 322 and 323 can decrease to the on-state, and radio-frequency signals can leak into the off signal path, thereby degrading isolation characteristics. In contrast, because the transistor 321 does not include a resistive element, the supply of the bias voltage output from the bias circuit 61 to the transistors 322 and 323 through the resistive elements 422 and 423 can be hindered. As a result, the degradation of isolation characteristics can be suppressed.

The transistor not including a resistive element coupling the drain and the source is not necessarily the transistor 321. It is sufficient that at least one of the transistors 321 to 323 does not include a resistive element coupling the drain and the source.

The transistor 315 includes a resistive element 415 coupling the source and the drain. The transistor 316 includes a resistive element 416 coupling the source and the drain. The transistor 314 does not include a resistive element coupling the source and the drain.

The transistor 325 includes a resistive element 425 coupling the source and the drain. The transistor 326 includes a resistive element 426 coupling the source and the drain. The transistor 324 does not include a resistive element coupling the source and the drain.

The resistive elements 415 and 416 prevent the transistors 315 and 316 from being damaged by external surge voltages. However, in the signal path (on signal path) in which the low-noise amplifier 11 is in the on-state, the bias voltage from the signal path can be supplied through the resistive elements 415 and 416. In this case, the threshold voltages of the transistors 315 and 316 can decrease to the on-state, and radio-frequency signals can leak into ground, thereby increasing transfer loss. In contrast, because the transistor 314 does not include a resistive element, the supply of the bias voltage through the resistive elements can be hindered.

The transistor not including a resistive element coupling the drain and the source is not necessarily the transistor 314. It is sufficient that at least one of the transistors 314 to 316 does not include a resistive element coupling the drain and the source.

The resistive elements 425 and 426 prevent the transistors 325 and 326 from being damaged by external surge voltages. However, in the signal path (on signal path) in which the low-noise amplifier 11 is in the on-state, the bias voltage from the signal path can be supplied through the resistive elements 425 and 426. In this case, the threshold voltages of the transistors 325 and 326 can decrease to the on-state, and radio-frequency signals can leak into ground, thereby increasing transfer loss. In contrast, because the transistor 324 does not include a resistive element, the supply of the bias voltage through the resistive elements can be hindered.

The transistor not including a resistive element coupling the drain and the source is not necessarily the transistor 324. It is sufficient that at least one of the transistors 324 to 326 does not include a resistive element coupling the drain and the source.

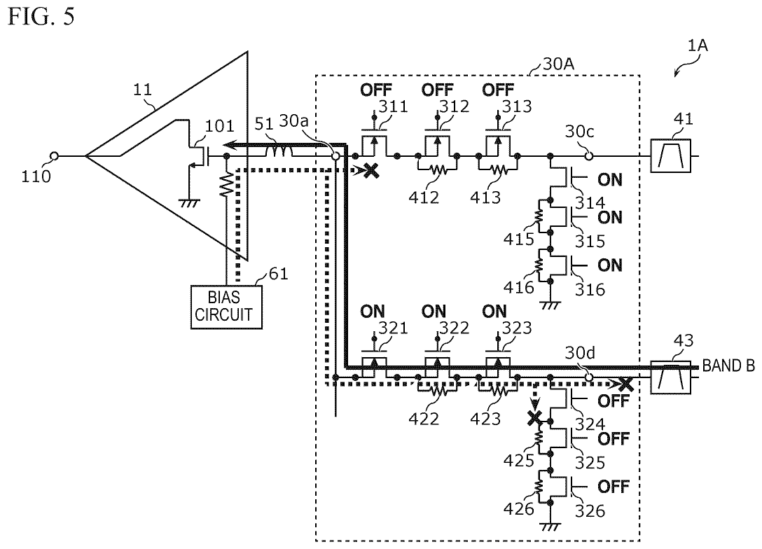

FIG. 5 illustrates a circuit state of the switching circuit 30A and adjacent circuits according to the modification during signal transfer. The drawing depicts the state of bias signal supply during the transfer of radio-frequency signals in the band B.

As illustrated in the drawing, during the transfer of radio-frequency signals in the band B, the terminals 30a and 30c are disconnected, and the terminals 30a and 30d are connected. To achieve this connection state, in the switching circuit 30A, the transistors 311 to 313 and the transistors 324 to 326 are in the off-state, and the transistors 314 to 316 and the transistors 321 to 323 are in the on-state.

At this time, in a path B (the filter 43—the terminal 30d—the transistors 323, 322, 321—the terminal 30a), which transfers radio-frequency signals in the band B, the transistors 321 to 323 are in the on-state. As a result, the bias voltage from the bias circuit 61 is applied to the sixth substrate of the transistor 321 through the source s21, to the seventh substrate of the transistor 322 through the source s22, and to the eighth substrate of the transistor 323 via the source s23. The bias voltage is not applied beyond the filter 43 to the antenna connection terminal 100 side. Because the transistor 324 includes no source-drain resistive element, the bias voltage cannot be applied to ground through the transistors 325 and 326.

In a path A (the filter 41—the terminal 30c—the transistors 313, 312, 311—the terminal 30a), which does not transfer radio-frequency signals in the band B, the transistors 311 to 313 are in the off-state. At this time, because the transistor 311 includes no source-drain resistive element, the bias voltage from the bias circuit 61 cannot be supplied to the transistors 312 and 313 through the resistive elements 412 and 413.

With this configuration, the substrate bias voltage supplied to the transistors 321 to 323 can be supplied, without necessarily requiring a dedicated path, from the bias circuit 61, which also supplies the bias voltage supplied to the low-noise amplifier 11, through the low-noise amplifier 11 and the terminal 30a. This configuration reduces the number of bias circuits, thereby miniaturizing the amplifier circuit 1A. Furthermore, the threshold voltage Vt of the transistors 321 to 323 can be lowered by applying a substrate bias voltage, thereby reducing the transfer loss Ron of the transistors 321 to 323. As a result, the amplifier circuit 1A is able to transfer radio-frequency signals with low loss. Because receive signals can be supplied to the low-noise amplifier 11 with low loss, degradation of receive sensitivity can be suppressed.

Because the transistor 324 does not include a source-drain resistive element, the supply of the bias voltage output from the bias circuit 61 to the transistors 325 and 326 through the resistive elements 425 and 426 can be hindered. As a result, the increase in transfer loss due to the leakage of radio-frequency signals to ground can be suppressed.

Because the transistor 311 does not include a source-drain resistive element, it is possible to suppress the supply to transistors 312 and 313 through the resistors 412 and 413. As a result, the degradation of isolation characteristics can be suppressed.

### 2. Effects

As described above, the amplifier circuit 1 according to the present embodiment includes the antenna connection terminal 100 configured to receive a radio-frequency signal, the low-noise amplifier 11 configured to amplify the radio-frequency signal, the switching circuit 30 coupled between the low-noise amplifier 11 and the antenna connection terminal 100, and the bias circuit 61 configured to supply a DC bias voltage to the low-noise amplifier 11. The switching circuit 30 includes the terminal 30a coupled to the low-noise amplifier 11 and the terminal 30c coupled to the antenna connection terminal, and the transistor 31 including the gate terminal g1 and the first substrate of p-type, configured to alternate the connection and disconnection between the terminals 30a and 30c in response to the voltage applied to the gate terminal g1. In the amplifier circuit 1, the bias circuit 61, the terminal 30a, and the first substrate are coupled for direct-current conduction.

With this configuration, the substrate bias voltage supplied to the transistor 31 can be supplied, without necessarily requiring a dedicated path, from the bias circuit 61, which also supplies the bias voltage supplied to the low-noise amplifier 11, through the low-noise amplifier 11 and the terminal 30a. This configuration reduces the number of bias circuits, thereby miniaturizing the amplifier circuit 1. Furthermore, the threshold voltage Vt of the transistor 31 can be lowered by applying a substrate bias voltage, thereby reducing the transfer loss Ron of the transistor 31. As a result, the amplifier circuit 1 can transfer radio-frequency signals with low loss. Because receive signals can be supplied to the low-noise amplifier 11 with low loss, degradation of receive sensitivity can be suppressed.

In an example, in the amplifier circuit 1, a DC bias voltage may be applied to the first substrate from the bias circuit 61 through the low-noise amplifier 11 and the terminal 30a.

With this configuration, the transfer loss Ron of the transistor 31 can be reduced. Additionally, when the low-noise amplifier 11 is in the off-state, the substrate bias voltage can be reduced, and the threshold voltage Vt can be increased, thereby reducing the off-leak current when radio-frequency signals are not amplified.

In an example, in the amplifier circuit 1, the first substrate may have an n-type source region coupled to the terminal 30a and an n-type drain region coupled to the terminal 30c. The transistor 31 may be a FET. The source may be coupled to the first substrate.

With this configuration, the substrate bias voltage can be applied through the source.

In an example, in the amplifier circuit 1A, the switching circuit 30A may include the transistor 311 provided in the path connecting the terminals 30a and 30c, and the transistor 314 coupled between ground and the path connecting the transistor 311 and the terminal 30c.

With this configuration, radio-frequency signals can be transferred with low loss by turning the transistors 311 and 314 on or off in an exclusive manner. Because the transistor coupled closest to the low-noise amplifier 11 is not the transistor 314 but rather the transistor 311, the leakage of the bias voltage to ground can be suppressed when the transistor 314 is in the on-state.

In an example, the amplifier circuit 1 may further include the filter 41 coupled between the antenna connection terminal 100 and the switching circuit 30, provided with an acoustic wave resonator.

Because acoustic wave filters exhibit capacitive characteristics, the filter 41 does not pass direct current signals, thereby preventing the bias voltage from leaking from the switching circuit 30 to the antenna connection terminal 100 side.

In an example, the amplifier circuit 1 may further include the inductor 51 having one end coupled to the input end of the low-noise amplifier 11 and another end coupled to terminal 30a. It may be possible that no inductor is provided between ground and the path connecting the input end of the low-noise amplifier 11 and the terminal 30a.

With this configuration, the inductor 51 is able to provide impedance matching between the low-noise amplifier 11 and the switching circuit 30. Because no inductor is provided between ground and the path, the bias voltage is prevented from leaking to ground and not being supplied to the switching circuit 30.

In an example, in the amplifier circuit 1A, the switching circuit 30A may include the transistors 311 to 313 coupled in series between the terminals 30a and 30c, and the transistors 314 to 316 coupled in series between ground and the path connecting the terminals 30a and 30c. Among the transistors 311 to 316, the transistor 311 may be coupled closest to the low-noise amplifier 11.

This configuration suppresses the leakage of the bias voltage to ground when the transistors 314 to 316 are in the on-state.

In an example, in the amplifier circuit 1A, the switching circuit 30A may further include the terminal 30d coupled to the antenna connection terminal 100, the transistors 321 to 323 coupled in series between the terminals 30a and 30d, and the transistors 324 to 326 coupled in series between ground and the path connecting the terminals 30a and 30d. Each of the transistors 321 to 323 may include a gate terminal, a p-type substrate, an n-type source provided within the substrate and coupled to the terminal 30a, and a p-type drain provided within the substrate and coupled to the terminal 30d. Each of the transistors 321 to 323 may be configured to alternate the connection and disconnection between the terminals 30a and 30d in response to a voltage supplied to the gate terminal. The bias voltage may be supplied from the bias circuit 61 to the substrate through the low-noise amplifier 11 and the terminal 30a. The transistors 312 and 313 may include a resistive element coupling the source and the drain. It may be possible that the transistor 311 does not include a resistive element coupling the source and the drain. The transistors 322 and 323 may include a resistive element coupling the source and the drain. It may be possible that the transistor 321 does not include a resistive element coupling the source and the drain.

With this configuration, the resistive element coupled between the source and the drain can prevent the switch from being damaged by external surge voltages. However, in the signal path (off signal path) in which the low-noise amplifier 11 is in the off-state, the bias voltage from other signal paths can be supplied through the resistive elements. The threshold voltages of the transistors can decrease to the on-state, and radio-frequency signals can leak into the off signal path, thereby degrading isolation characteristics. In contrast, because the transistors 311 and 321 do not include a resistive element, the supply of the bias voltage through the resistive elements can be hindered. As a result, the degradation of isolation characteristics can be suppressed.

In an example, in the amplifier circuit 1A, the transistors 315 and 316 may include a resistive element coupling two terminals that are to be brought into the on-state or the off-state. It may be possible that the transistor 314 does not include a resistive element coupling two terminals that are to be brought into the on-state or the off-state. The transistors 325 and 326 may include a resistive element coupling two terminals that are to be brought into the on-state or the off-state. It may be possible that the transistor 324 does not include a resistive element coupling two terminals that are to be brought in the on-state or the off-state.

With this configuration, in the signal path in which the low-noise amplifier 11 is in the on-state, the bias voltage can be supplied from the signal path through the resistive element. As a result, the threshold voltage of the off-state transistors 314 to 316 or 324 to 326 is lowered to the on-state, thereby suppressing the leakage of radio-frequency signals to ground.

The communication device 4 according to the present embodiment includes the amplifier circuit 1 and the RFIC 3 configured to process a radio-frequency signal transferred or to be transferred by the amplifier circuit 1.

This configuration enables the communication device 4 to achieve the same effects as the amplifier circuit 1.

### OTHER EMBODIMENTS

The amplifier circuit and the communication device according to an embodiment have been described by using the embodiment and modification, but the amplifier circuit and the communication device according to the present disclosure are not limited to the embodiment and modification. The present disclosure also embraces other embodiments implemented as any combination of the constituent elements of the embodiment and modification, other modifications obtained by making various modifications to the embodiment that occur to those skilled in the art without necessarily departing from the scope of the present disclosure, and various hardware devices including the amplifier circuit or the communication device according to the present disclosure.

For example, in the amplifier circuit and the communication device according to the embodiment and modification described above, other radio-frequency circuit elements and wire lines may be inserted in the paths connecting the circuit elements and signal paths that are illustrated in the drawings.

The following describes the features of the amplifier circuit and the communication device explained based on the embodiment.

<1>

An amplifier circuit comprising:

a first input terminal configured to receive a radio-frequency signal;

an amplifier configured to amplify the radio-frequency signal;

a switching circuit coupled between the amplifier and the first input terminal; and

a bias circuit configured to supply a direct-current bias voltage to the amplifier, wherein

the switching circuit includes
a first terminal coupled to the amplifier, and a second terminal coupled to the first input terminal, and
a first switch including a transistor that has a first control terminal, a first substrate of a first conductivity type, a first region of a second conductivity type provided within the first substrate and coupled to the first terminal, and a second region of the second conductivity type provided within the first substrate and coupled to the second terminal, the first switch being configured to alternate connection and disconnection between the first terminal and the second terminal in response to a voltage applied to the first control terminal, and

the bias circuit, the first terminal, and the first substrate are coupled for direct-current conduction.

<2>

The amplifier circuit according to <1>, wherein

the bias voltage is applied from the bias circuit to the first substrate through the amplifier and the first terminal.

<3>

The amplifier circuit according to <1> or <2>, wherein

the first switch includes a field-effect transistor,

the first region is a source region,

the second region is a drain region,

the first control terminal is a gate terminal, and

the first region is coupled to the first substrate.

<4>

The amplifier circuit according to any of <1> to <3>, wherein

the switching circuit further includes
a second switch coupled between ground and a path connecting the first switch and the second terminal.

<5>

The amplifier circuit according to any of <1> to <4>, wherein

the amplifier is a low-noise amplifier configured to amplify a receive signal that is input from the first input terminal.

<6>

The amplifier circuit according to any of <1> to <5>, further comprising:

an acoustic wave filter coupled between the first input terminal and the switching circuit.

<7>

The amplifier circuit according to any of <1> to <6>, further comprising:

an inductor having one end coupled to an input end of the amplifier and another end coupled to the first terminal, wherein

no inductor is provided between ground and a path connecting the input end of the amplifier and the first terminal.

<8>

The amplifier circuit according to <4>, wherein

the switching circuit includes
one or more first switches coupled in series between the first terminal and the second terminal, each first switch including a transistor that has a first control terminal and a first substrate of the first conductivity type, the first switch being configured to alternate connection and disconnection between the first terminal and the second terminal in response to a voltage applied to the first control terminal, and
one or more second switches coupled in series between ground and a path connecting the first terminal and the second terminal, each second switch being coupled between ground and a path connecting the first switch and the second terminal, and

among the one or more first switches and the one or more second switches, any of the one or more first switches is coupled closest to the amplifier.

<9>

The amplifier circuit according to <8>, further comprising:

a second input terminal configured to receive a radio-frequency signal, wherein

the switching circuit further includes
a third terminal coupled to the second input terminal,
one or more third switches coupled in series between the first terminal and the third terminal, and
one or more fourth switches coupled in series between ground and a path connecting the first terminal and the third terminal,

the third switch includes a second control terminal, a second substrate of the first conductivity type, a third region of the second conductivity type provided within the second substrate and coupled to the first terminal, and a fourth region of the second conductivity type provided within the second substrate and coupled to the third terminal, and the third switch is configured to alternate connection and disconnection between the first terminal and the third terminal in response to a voltage supplied to the second control terminal,

the bias voltage is supplied from the bias circuit to the second substrate through the amplifier and the first terminal,

one of the one or more first switches includes a resistive element coupling the first region and the second region,

another of the one or more first switches does not include a resistive element coupling the first region and the second region,

one of the one or more third switches includes a resistive element coupling the third region and the fourth region, and

another of the one or more third switches does not include a resistive element coupling the third region and the fourth region.

<10>

The amplifier circuit according to <9>, wherein

one of the one or more second switches includes a resistive element coupling two terminals that are to be connected or disconnected,

another of the one or more second switches does not include a resistive element coupling two terminals that are to be connected or disconnected,

one of the one or more fourth switches includes a resistive element coupling two terminals that are to be connected or disconnected, and

another of the one or more fourth switches does not include a resistive element coupling two terminals that are to be connected or disconnected.

<11>

A communication device comprising:

the amplifier circuit according to any of <1> to <10>; and

a radio-frequency (RF) signal processing circuit configured to process a radio-frequency signal transferred or to be transferred by the amplifier circuit.

### INDUSTRIAL APPLICABILITY

The present disclosure can be used as a front-end circuit that supports multiple bands and multiple modes, in a wide variety of communication devices such as mobile phones.

### REFERENCE SIGNS LIST

1, 1A, 500 amplifier circuit
2 antenna
3 RF signal processing circuit (RFIC)
4 communication device
11, 12 low-noise amplifier
20, 30, 30A, 530 switching circuit
20a, 20b, 20c, 20d, 20e, 20f, 30a, 30b, 30c, 30d, 30e, 30f, 30g terminal
31, 32, 311, 312, 313, 314, 315, 316, 321, 322, 323, 324, 325, 326, 531, 532 transistor
41, 42, 43, 44, 45, 46, 47, 48 filter
51, 52, 53 inductor
54 capacitor
61, 62, 63 bias circuit
100 antenna connection terminal
101 amplifier transistor
110, 120 radio-frequency output terminal
412, 413, 415, 416, 422, 423, 425, 426 resistive element
d1, d2, d11, d12, d13, d21, d22, d23 drain
g1, g2, g11, g12, g13, g21, g22, g23 gate terminal
s1, s2, s11, s12, s13, s21, s22, s23 source

1. An amplifier circuit comprising:
a first input terminal configured to receive a radio-frequency signal;
an amplifier configured to amplify the radio-frequency signal;
a switching circuit coupled between the amplifier and the first input terminal; and
a bias circuit configured to supply a direct-current bias voltage to the amplifier,
wherein the switching circuit comprises:
a first terminal coupled to the amplifier, and a second terminal coupled to the first input terminal, and
a first switch comprising a first transistor that has a first control terminal and a first substrate of at least a first conductivity type, the first switch being configured to selectively connect the first terminal and the second terminal in response to a voltage applied to the first control terminal, and
wherein the bias circuit, the first terminal, and the first substrate are coupled for direct-current conduction.

2. The amplifier circuit according to claim 1, wherein the bias circuit is configured to apply the bias voltage to the first substrate through the amplifier and the first terminal.

3. The amplifier circuit according to claim 1,
wherein the first substrate has a first region of a second conductivity type coupled to the first terminal and a second region of the second conductivity type coupled to the second terminal,
wherein the first switch comprises a field-effect transistor,
wherein the first region is a source region and the second region is a drain region,
wherein the first control terminal is a gate terminal, and
wherein the first region is coupled to the first substrate.

4. The amplifier circuit according to claim 1, wherein the switching circuit further comprises a second switch coupled between ground and a path connecting the first switch and the second terminal.

5. The amplifier circuit according to claim 1, wherein the amplifier is a low-noise amplifier configured to amplify a receive signal from the first input terminal.

6. The amplifier circuit according to claim 1, further comprising:
an acoustic wave filter coupled between the first input terminal and the switching circuit.

7. The amplifier circuit according to claim 1, further comprising:
an inductor having a first end coupled to an input end of the amplifier and a second end coupled to the first terminal,
wherein there is no inductor between ground and a path connecting the input end of the amplifier and the first terminal.

8. The amplifier circuit according to claim 4,
wherein the switching circuit further comprises:
a plurality of the first switches, each coupled in series between the first terminal and the second terminal, and
a plurality of the second switches, each coupled in series between ground and the path connecting the first terminal and the second terminal, and
wherein among the plurality of first switches and the plurality of second switches, any of the plurality of first switches is coupled closest to the amplifier.

9. The amplifier circuit according to claim 8, further comprising:
a second input terminal configured to receive a second radio-frequency signal,
wherein the switching circuit further comprises:
a third terminal coupled to the second input terminal,
one or more third switches coupled in series between the first terminal and the third terminal, and
one or more fourth switches coupled in series between ground and a path connecting the first terminal and the third terminal,
wherein the first substrate has a first region of a second conductivity type coupled to the first terminal and a second region of the second conductivity type coupled to the second terminal,
wherein the third switch has a second control terminal, and a second substrate of the first conductivity type, the third switch being configured to selectively connect the first terminal and the third terminal in response to a voltage supplied to the second control terminal,
wherein the second substrate has a third region of the second conductivity type coupled to the first terminal and a fourth region of the second conductivity type coupled to the third terminal,
wherein the bias circuit is configured to supply the bias voltage to the second substrate through the amplifier and the first terminal,
wherein one of the plurality of first switches comprises a resistive circuit element coupling the first region and the second region,
wherein another of the plurality of first switches does not comprise a resistive circuit element coupling the first region and the second region,
wherein one of the one or more third switches comprises a resistive circuit element coupling the third region and the fourth region, and
wherein another of the one or more third switches does not comprise a resistive circuit element coupling the third region and the fourth region.

10. The amplifier circuit according to claim 9,
wherein one of the plurality of second switches comprise a resistive circuit element coupling two terminals that are selectively connected to each other,
wherein another of the plurality of second switches does not comprise a resistive circuit element coupling two terminals that are selectively connected to each other,
wherein one of the one or more fourth switches comprises a resistive circuit element coupling two terminals that are selectively connected to each other, and
wherein another of the one or more fourth switches does not comprise a resistive circuit element coupling two terminals that are selectively connected to each other.

11. A communication device comprising:
the amplifier circuit according to claim 1; and
a radio-frequency (RF) signal processing circuit configured to process radio-frequency signals amplified, or to be amplified, by the amplifier circuit.
